(19) United States
(12) Patent Application Publication
(10) Pub. No.: US 2022/0139674 A1
(43) Pub. Date: May 5, 2022

(54) SYSTEMS AND METHODS COMBINING MATCH NETWORKS AND FREQUENCY TUNING

(71) Applicant: Advanced Energy Industries, Inc., Fort Collins, CO (US)

(72) Inventors: Denis Shaw, Fort Collins, CO (US); Myeong Yeol Choi, Fort Collins, CO (US)

(21) Appl. No.: 17/510,566

(22) Filed: Oct. 26, 2021

Related U.S. Application Data
(60) Provisional application No. 63/107,001, filed on Oct. 29, 2020.

(51) Int. Cl. H01J 37/32; H03H 7/38

(52) U.S. Cl. CPC H01J 37/32183; H01J 2237/334; H03H 7/38

(57) ABSTRACT

A power system for a plasma processing system and associated methods are disclosed. The power system comprises a generator with a frequency-tuning subsystem, a match network coupled between the plasma processing chamber and the generator, and means for adjusting an impedance of the match network so the frequency-tuning subsystem adjusts a frequency of power applied by the generator to a target frequency while the match network presents a desired impedance to the generator in response to variations in an impedance of a plasma in a plasma processing chamber.

### CLAIM OF PRIORITY UNDER 35 U.S.C. § 119

The present Application for Patent claims priority to Provisional Application No. 63/107,001 entitled “Systems and Methods Combining Match Networks and Frequency Tuning” filed Oct. 29, 2020, and assigned to the assignee hereof and hereby expressly incorporated by reference herein.

### BACKGROUND

### Field

The present disclosure relates generally to plasma processing systems, and more specifically, to impedance matching in plasma processing systems.

### Background

In plasma processing, generators are used to supply power to a plasma load. Today's advanced plasma processes include ever more complicated recipes and recipe-changing procedures in which the plasma load impedance dynamically changes. This can make it challenging to match the source impedance of the generator with the plasma load for efficient power transfer. Such impedance matching can be performed using a matching network, but this approach is relatively slow in the context of modern short-duration plasma processes. An alternative approach is to adjust the frequency of the generator, which alters the impedance of the plasma load. “Plasma load,” in this context, includes the plasma itself, components associated with a plasma processing chamber, and any matching network.

But conventional frequency-tuning algorithms are often disfavored because the frequency that is applied to the plasma load (including the plasma processing chamber) varies; thus, creating inconsistent power conditions when processing workpieces (e.g., substrates) in the plasma processing chamber. These inconsistent conditions may cause inconsistency across the processed workpieces, which in many instances is very undesirable. There is, therefore, a need in the art for an improved apparatus for performing matching in a plasma processing system.

### SUMMARY

According to an aspect, a match network comprises an input configured to couple to a generator, an output configured to couple a plasma processing chamber, and a measurement section is configured to provide an output indicative of an impedance of a plasma load presented to the generator. The match network also comprises variable reactive elements and a controller. The controller is configured to obtain a target frequency of the generator, obtain an actual frequency applied by the generator, and adjust the variable reactive elements based on the output indicative of the impedance of a plasma load so the generator adjusts its frequency to the target frequency.

According to another aspect, a power system for a plasma processing system is disclosed. The power system comprises a generator with a frequency-tuning subsystem and a match network. The power system also comprises means for adjusting an impedance of the match network so the frequency-tuning subsystem adjusts a frequency of power applied by the generator to a target frequency while the match network presents a desired impedance to the generator in response to variations in an impedance of a plasma load.

According to yet another aspect, a method for impedance matching is disclosed. The method comprises applying power with a generator to a plasma load that comprises a match network, obtaining one or more parameter values indicative of an impedance of the plasma load presented to the generator, obtaining a target frequency of the generator, obtaining an actual frequency of the power applied by the generator, and creating, based upon a difference between the target frequency and the actual frequency, a mismatch between a source impedance of the generator and the plasma load by adjusting a variable reactance section of a match network. A frequency of the generator is adjusted to remove the mismatch between the source impedance of the generator and the plasma load, wherein the frequency of the generator is the target frequency when the mismatch is removed.

Another aspect may be characterized as a non-transitory computer-readable medium comprising instructions for operating a match network, for execution by a processor or for configuring a field programmable gate array. The instructions comprise instructions to obtain one or more parameter values indicative of an impedance of a plasma load, obtain a target frequency of the generator, obtain an actual frequency of the power applied by the generator, and create, based upon a difference between the target frequency and the actual frequency, a mismatch between a source impedance of the generator and the plasma load by adjusting a variable reactance section of a match network.

### BRIEF DESCRIPTION OF THE DRAWINGS

FIG. 1 is a block diagram of a plasma processing system in accordance with an embodiment of this disclosure;

FIG. 2 is a block diagram depicting exemplary components of an element controller;

FIG. 3 is a block diagram depicting an exemplary variable reactance section;

FIG. 4 is a flowchart of a method that may be traversed in connection with embodiments of this disclosure;

FIG. 5 includes graphs of frequency, reflection coefficient (gamma), and capacitor position according to typical modes of operation with a generator that operates at a fixed frequency;

FIG. 6 includes graphs of frequency, reflection coefficient (gamma), and capacitor position according to a matching approach that is consistent with the method depicted in FIG. 4;

FIG. 7 is a block diagram of a generator 702 in accordance with an embodiment of this disclosure;

FIG. 8 is an illustration of a complex-reflection-coefficient (F) plane 800 in accordance with an embodiment of this disclosure;

FIG. 9 is a flowchart of a method for tuning the frequency of the generator in accordance with an embodiment of this disclosure; and

FIG. 10 is a block diagram depicting physical components that may be used to implement a frequency-tuning subsystem in accordance with an embodiment of this disclosure.

### DETAILED DESCRIPTION

The following modes, features or aspects, given by way of example only, are described in order to provide a more precise understanding of the subject matter of several embodiments.

As disclosed herein, a match network may comprise an input configured to couple to a generator, an output configured to couple a plasma processing chamber, a measurement section configured to provide an output indicative of an impedance of a plasma load presented to the generator, and a variable reactance section including a tuning element and a frequency-affecting element. In addition, the match network may include an element controller configured obtain a value of the impedance presented to the generator, obtain a target frequency of the generator, obtain an actual frequency applied by the generator, and set a position of a tuning element of the match network, wherein the tuning element is an adjustable reactive element of the match network, and the element controller may set a position of a frequency-affecting element of the match network so the generator adjusts its frequency to the target frequency.

The match network may set the position of the frequency-affecting element by setting the position as a function of a difference between the actual frequency and the target frequency. And the frequency-affecting element may be a series capacitance of the match network.

Also disclosed herein is a plasma processing system that may comprise a generator with a frequency-tuning subsystem, a plasma processing chamber, a match network coupled between the plasma processing chamber and the generator, and means for adjusting an impedance of the match network so the frequency-tuning subsystem adjusts a frequency of power applied by the generator to a target frequency while the match network presents a desired impedance to the generator in response to variations in an impedance of a plasma in the plasma processing chamber.

The match network of the plasma processing system may comprise a tuning element, a frequency-affecting element, and an element controller. And the element controller may be configured to obtain a value of the impedance presented to the generator, obtain the target frequency of the generator, obtain an actual frequency of the power applied by the generator, set a position of a tuning element of the match network as a function of a difference between the actual frequency and the target frequency, and set a position of a frequency-affecting element of the match network so the generator adjusts its frequency to the target frequency. The tuning element may be an adjustable reactive element of the match network.

One or more methods disclosed herein may comprise applying power with a generator to a plasma load that comprises a match network, obtaining one or more parameter values indicative of an impedance of the plasma load presented to the generator, obtaining a target frequency of the generator, obtaining an actual frequency of the power applied by the generator, creating, based upon a difference between the target frequency and the actual frequency, a mismatch between a source impedance of the generator and the plasma load by adjusting a variable reactance section of a match network, and adjusting a frequency of the generator to remove the mismatch between the source impedance of the generator and the plasma load, wherein the frequency of the generator is the target frequency when the mismatch is removed.

A position of a tuning element of the match network may be based upon an impedance mismatch that exists, at the actual frequency, between the source impedance of the generator and the plasma load; and the position of a frequency-affecting element of the match network may be set as a function of the difference between the actual frequency and the target frequency, the position of the frequency-affecting element creates the mismatch between a source impedance of the generator and the plasma load.

The position of the tuning element of the match network may comprise adjusting a reactive element of the match network to match a resistance of the plasma load to a real part of the source impedance, and setting the position of the frequency-affecting element may create a mismatch between reactance portions of the plasma load and the source impedance of the generator when there is a difference between the target frequency and the actual frequency.

A position of the tuning element of the match network may be set by setting a position of a reactive element arranged in parallel with a plasma chamber, and setting a position of the frequency-affecting element may comprise adjusting a position of a reactive element arranged in series with a plasma chamber.

The mismatch created between a source impedance of the generator and the plasma load may be created by adjusting a series capacitor of the match network, and the frequency of the generator may be simultaneously adjusted while adjusting a shunt capacitor of the match network to match imaginary portions of the source impedance of the generator and the plasma.

The word “exemplary” is used herein to mean “serving as an example, instance, or illustration.” Any embodiment described herein as “exemplary” is not necessarily to be construed as preferred or advantageous over other embodiments.

Several embodiments disclosed herein combine match tuning (of a match network) with frequency tuning (of a generator) and enable fast tuning of an impedance matching network while being compatible with existing, or yet to be developed, generator-frequency-tuning algorithms More specifically, an aspect of the present disclosure is an approach to control a match network that is compatible with a variety of frequency tuning algorithms Utilization of the match network control algorithms disclosed herein may contribute to reduced reflected power, which may reduce stresses placed on generators (such as medium and radio-frequency) generators. As a consequence, aspects disclosed herein may increase the reliability of generators while improving a quality of an application process by producing less reflected power.

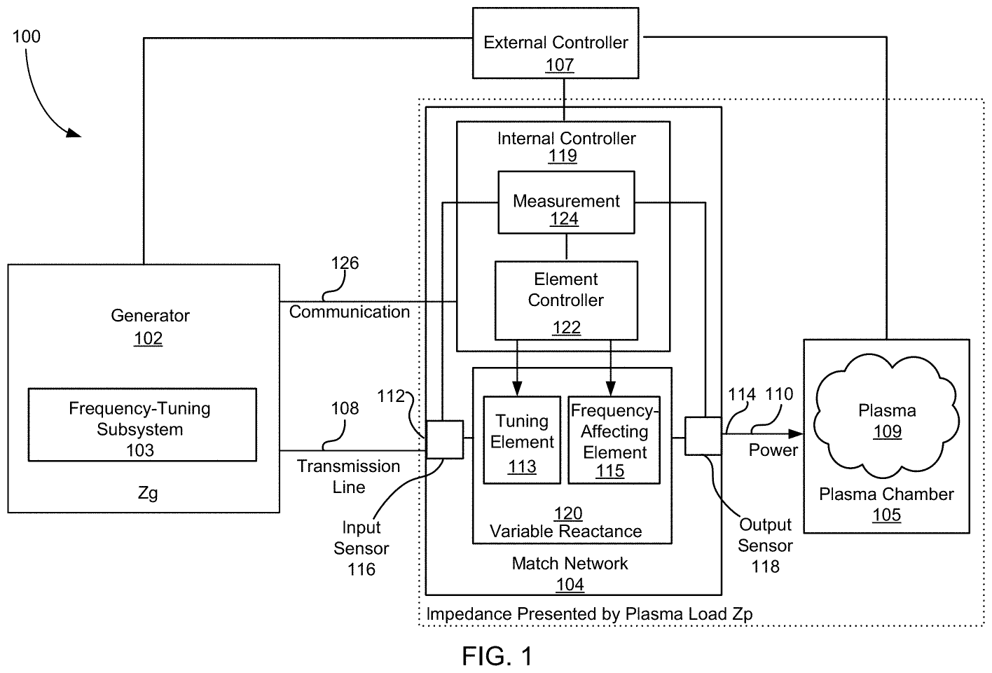

Referring first to FIG. 1, shown is a plasma processing system 100 including a generator 102, match network 104, a plasma processing chamber 105, and an external controller 107. In operation, the generator 102 applies power (e.g., medium frequency power, radio frequency (RF) power, or power at any frequency where impedance matching is beneficial) to the match network 104 via a transmission line 108 (e.g., coaxial cable) and then onto the plasma chamber 105 via an electrical connection 110. The generator 102 may be realized by a variety of different types of generators that may operate at a variety of different power levels and frequencies. In this embodiment, the generator 102 includes a frequency-tuning subsystem 103 that is configured to adjust a frequency of the generator 102.

The match network 104 includes an input 112 including an electrical connector (not shown) to couple to the generator 102 via the transmission line 108 and an output 114 including an electrical connector (not shown) to couple to the plasma chamber 105 via the electrical connection 110. As shown, the match network 104 also includes an input sensor 116 and an output sensor 118 that are both coupled to an internal controller 119, which includes a measurement section 124, an element controller 122, and a variable reactance section 120.

As shown, the variable reactance section 120 may include a tuning element 113 and a frequency-affecting element 115. It should be recognized that the tuning element 113 and the frequency-affecting element 115 represent logical functions of portions of the variable reactance section 120. More specifically, each of the tuning element 113 and the frequency-affecting element 115 may be realized by reactive components, and the arrangement of the reactive elements may be consistent with known match architectures. For example, without limitation, the variable reactance portion 120 may be arranged in a “π,” “T,” or “L” type of architecture.

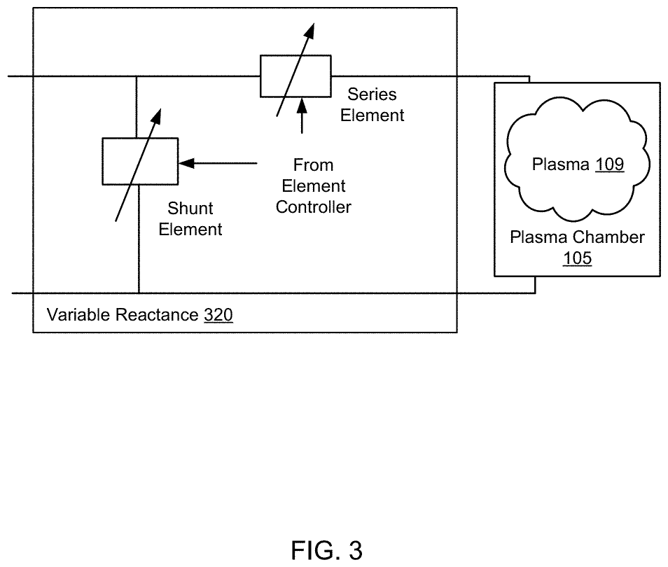

Regardless of the type of architecture that is utilized, those of ordinary skill in the art will appreciate (in view of this disclosure) that the frequency-affecting element 115 may comprise one or more frequency-affecting elements that primarily affect the imaginary part of the impedance presented to the generator 102, and as a consequence, these one or more frequency-affecting elements primarily affect the frequency that the generator 102 will adjust to. In some architectures (e.g., as described with reference to FIG. 3), the frequency-affecting element 115 comprises one or more series elements (e.g., one or more series capacitors), but as used herein the frequency-affecting element 115 refers to reactive elements that primarily affect the imaginary part of the impedance presented to the generator 102. Those of ordinary skill in the art will also appreciate (in view of this disclosure) that the tuning element 113 may comprise one or more tuning elements that primarily affect the real part of the impedance presented to the generator 102. In some architectures (e.g., as described with reference to FIG. 3), the tuning element 113 comprises one or more shunt elements (e.g., one or more shunt capacitors).

Although not shown to keep the depiction of FIG. 1 simple and clear, one of ordinary skill in the art will readily appreciate that the generator 102, the match network 104, and/or the external controller 107 may include a user interface to enable an operator of the plasma processing system 100 to control and monitor the plasma processing system 100. It should also be noted that the depiction of the external controller 107 should not be construed to mean that common supervisory control over the generator 102 and match network 104 is required. More specifically, the match network 104 may operate (as described below) without a control signal from the external controller 107 to achieve a target frequency of the generator 102. This is in contrast to prior art approaches to effectuating impedance matching that utilize a supervisory controller to control both frequency tuning of a generator and the match network.

The plasma 109 may be a plasma formed in the plasma processing chamber 105, which is known for performing processing such as the etching of substrates or the deposition of thin layers upon substrates. The plasma 109 is typically achieved by the formation of plasmas within low pressure gases. The plasma is initiated and sustained by the generator 102 (and potentially additional generators), and the match network 104 is employed to ensure the generator 102 sees a desired impedance (typically, although not always, 50 ohms) at the output of the generator 102. As shown, the impedance presented to the generator 102 by the plasma load, Zp, includes the plasma 109 itself, components associated with a plasma processing chamber 105, and the matching network 104.

The generator 102 may apply power to the plasma chamber 105 by a conventional 13.56 MHz signal, but other frequencies may also be utilized. The generator 102 may have a source impedance, Zg, of 50 ohms and an output stage to match the source impedance of the generator 102 to the impedance of the transmission line 108, which may be a typical transmission line (such as a 50 ohm coaxial cable). The source impedance of the generator, Zg, may be 50 ohms, but those of ordinary skill in the art of plasma processing systems will appreciate that, depending upon the particular type (e.g., design architecture, make, and/or model) of generator used to realize the generator 102, the source impedance, Zg, of the generator 102 may differ from 50 ohms.

The external controller 107 may be realized by hardware or hardware in connection with software, and the external controller 107 may be coupled to several components of a plasma processing system 100 including the generator 102, match network 104, equipment coupled to the plasma chamber 105, other generators, mass flow controllers, etc.

In general, the match network 104 in connection with the frequency-tuning subsystem 103 functions to transform an impedance at the output 114 of the match network 104 to a desired impedance value for the plasma load, Zp, (that is presented to the transmission line 108 at an input 112 of the match network 104) while maintaining (or moving in the direction of) the target frequency. The target frequency may be a frequency that is set by an operator of the plasma processing system, or the target frequency may be automatically set based upon operating conditions of the plasma processing system 100. As an example of the target frequency being automatically set, the internal controller 119 may be configured to set and provide the target frequency to the element controller 222 after a value of a power parameter, such as reflected power, is maintained for a threshold period of time. By way of further example, the internal controller 119 may monitor a reflection coefficient, and if the reflection coefficient is maintained at a minimum value (at a particular frequency) for the threshold period of time (e.g., ten seconds), the internal controller 119 may set the target frequency to the particular frequency.

The desired value for the impedance of the plasma load, Zp, may be a complex conjugate of the source impedance, Zg, of the generator 102 (to provide complex conjugate matching), or the desired value for the impedance of the plasma load, Zp, may intentionally be offset from the source impedance, Zg, of the generator 102. As described in more detail further herein, the algorithm carried out by the element controller 122 of the match network 104 is designed with the assumption that the frequency-tuning subsystem 103 of the generator 102 will operate to adjust the frequency of the generator 102 when the generator 102 sees an impedance at the transmission line 108 that is not the desired value for the impedance of the plasma load, Zp. In other words, the match network 104 is designed to complement the operation of the frequency-tuning subsystem 103.

Regardless of whether the desired value for the impedance of the plasma load, Zp, is matched to the source impedance, Zg, of the generator 102 (e.g., complex conjugate matched) or offset from the source impedance, Zg, of the generator 102, the match network 104 functions to operate so that when the desired value for the impedance of the plasma load, Zp, is reached, the generator 102 is operating at the predetermined target frequency without the frequency-tuning subsystem 103 being disabled. More specifically, the element controller 122 of the match network 104 adjusts the frequency-affecting element 115 to a setting that prompts the frequency-tuning subsystem 103 to change the operating frequency of the generator 102 to the predetermined target frequency. In other words, the frequency-tuning subsystem 103 remains engaged to continue to adjust the frequency of the generator 102 based upon an impedance presented to the generator 102. As discussed further herein, the frequency tuning subsystem 103 may receive measurements indicative of an impedance of the plasma load, Zp (e.g., measurements indicative of reflected power) from one or more sensors and the frequency tuning subsystem 103 processes those measurements to produce frequency adjustments in the generator 102. This is beneficial because, in many instances, it is desirable to process workpieces in the plasma chamber 105 at a consistent frequency (e.g., to achieve a more consistent process result).

This functionality of the match network 104 is in contrast to prior art match networks because prior art match networks operate in a way that conflicts with the frequency-tuning algorithm of the frequency-tuning subsystem 103 and/or the frequency-tuning subsystem will vary the frequency of the generator 102 (to a frequency other than the target frequency) to achieve a desired impedance of the plasma load, Zp. That is, in prior approaches, the frequency of the generator 102 may be different at different times even though the desired impedance of the plasma load, Zp, has been reached at each of the different times. Some prior art approaches attempt to maintain a desired generator frequency using a more complicated control approach (e.g., using a supervisory controller) to operate in two modes to achieve a desired generator frequency. For example, some prior art approaches use a supervisory controller to operate in a first mode that allows a matching network to be controlled simultaneously with a frequency tuning algorithm of a generator, but when the frequency of the generator departs from a target frequency, a second mode of operation is initiated in which the automated-frequency-tuning capability of the generator is disabled, and the generator is forced to a target frequency (e.g., by slow adjusting the generator in a stepwise manner to the target frequency).

An aspect of many implementations is that the match network 104 may operate with any automatic frequency-tuning-enabled generator (while the automatic frequency-tuning capability of the generator is engaged), without being commonly controlled with the generator, to effectuate a desired, target frequency. More specifically, the match network 104 of the present disclosure will operate so that when the desired value of the impedance of the plasma load, Zp, is reached, the frequency applied by the generator 102 will be the predetermined target frequency; thus, creating consistency in processing frequency, and hence, more consistency when processing a workpiece. It should be recognized that the values of power-related parameters referred to herein (e.g., voltage, current, impedance, forward power, reflected power, and delivered power) are generally complex numbers that may be represented in terms of a real part and an imaginary part. Impedance, Z, for example may be represented in terms of resistance “R” (real part) and reactance “X” (imaginary part): Z=R+Xj where j is the square root of negative 1.

Within the match network 104, the element controller 122 of the match network 104 may operate the tuning element 113 in a typical manner to transform a portion of the impedance (e.g., a real portion) at the output 114 of the match network 104 to an input-impedance that is presented to the transmission line 108 at an input of the match network 104. More particularly, as those of ordinary skill in the art will readily appreciate, the measurement section 124 may receive signals from the input sensor 116 that are indicative of electrical parameter values at the input 112 of the match network 104. In turn, the measurement section 124 may provide one or more processed signals to the element controller 122, which controls a setting of the variable reactance section 120, and hence, the tuning element 113 such that the input impedance of the match network 104 is adjusted. But unlike prior art approaches, the element controller 122 operates (when a present frequency of the generator 102 is not equal to the target frequency) to adjust the frequency-affecting element 115 so that the frequency-tuning subsystem 103 will automatically adjust the frequency of the generator 102 to the predetermined target frequency.

Also shown is an output sensor 118, which may be used in addition to, or instead of, the input sensor 116. The input sensor 116 and/or the output sensor 118 may be realized by a conventional dual directional coupler (known to those of ordinary skill in the art) that includes sensing circuitry that provides outputs indicative of forward and reflected power at the input of the match network 104. The input sensor 116 and/or the output sensor 118 may also be realized by a conventional voltage-current (V/I) sensor (known to those of ordinary skill in the art) that includes sensing circuitry that provides outputs indicative of voltage, current, and a phase between the voltage and current. As a nonlimiting example, a directional coupler may be used to realize the input sensor 116 and a V/I sensor may be used to realize the output sensor 118. The input sensor 116 and/or the output sensor 118 may also comprise a frequency sensor known to those of ordinary skill in the art. Moreover, each of the input and output sensors 116, 118 may be realized by more than one separate sensors (e.g., a separate voltage sensor and a separate current transducer). In other words, although a single block is depicted for each of the input sensor 116 and output sensor 118, the single blocks each represent one or more sensors (and potentially processing circuitry).

The measurement section 124 may include processing components to sample, filter, and digitize the outputs of the input sensor 116 for utilization by the element controller 122. It is also contemplated that signals from the output sensor 118 may be utilized to control the variable reactance section 120. In any event, as discussed further herein, the element controller 122 may adjust the variable reactance component 120 to present an impedance to the transmission line 108 (and hence the generator 102) that is mismatched while the frequency of the generator 102 is at a frequency other than the target frequency. In this way, the frequency-tuning subsystem 103 of the generator 102 may simultaneously adjust the frequency of the generator 102 to both, arrive at the desired value for the impedance of the plasma load, Zp, and to arrive at the target frequency. The algorithm implemented by the match network 104 to accomplish this result will be clearer with reference to examples that follow.

Because an impedance of the plasma load, Zp, tends to vary during processing of a workpiece (e.g., a substrate), the element controller 122 may operate on an ongoing basis to adjust the variable reactance section 120 to change its impedance to compensate for fluctuations in the impedance of the plasma load.

In some variations, a communication link 126 communicatively couples the generator 102 and the match network 104 to enable informational and/or control signals to be sent between the generator 102 and the match network 104. For example, a target frequency desired by an operator of the plasma processing system 100 and/or an actual frequency of the power applied by the generator 102 may be communicated to the internal controller 119 via the communication link 126.

But many implementations do not require the communication link 126, and it should be recognized that in these implementations the match network 104 may operate substantially independent of the generator 102. The specific embodiment of the match network 104 in FIG. 1 (in which the element controller 122 and the measurement section 124 are within the internal controller 119 of the match network 104) may be beneficial for one or more reasons. For example, the internal controller 119 of the match network 104 may have access to internal parameters of the match network 104 that the external controller 107 (or other external controllers) does not have access to. As another example, the internal controller 119 is in closer proximity to the sensors 116, 118; thus, data from the sensors 116, 118 may be received and processed relatively quickly. In addition, the components of the internal controller 119 may be realized on the same printed circuit board or even the same chip (as a system on a chip); thus, very fast bus communications (without the need to translate to another communication protocol, such as a local area network protocol) may be carried out between the components of some embodiments of the internal controller 119.

But in variations of the embodiment depicted in FIG. 1, it may be beneficial to distribute one or more of the components of the match network 104 and/or generator 108, so other configurations are certainly contemplated. For example, one or both of the input sensor 116 and output sensor 118 may be located outside of the match network 104. As another example, the input sensor 116 may reside within the generator 102 and the generator 102 may provide a signal indicative of electrical parameters at the output of the generator 102 to the measurement section 124. Moreover, one or more of the components of the internal controller 119 (e.g., one or more of the element controller 122 and measurement section 124 may be located apart from the match network 104).

For example, it is contemplated that one or more components of the internal controller 119 may be located remotely from the match network 104 and may be coupled to the match network 104, the generator 102, or the external controller 107 by a network connection. It is also contemplated that the frequency-tuning subsystem 103 may be realized, at least in part in the external controller 107. In many instances, operators of plasma processing systems (such as the system depicted in FIG. 1) may prefer to utilize a centralized controller (such as the external controller 107) for convenience, and because the operators may prefer to have control over the logic and algorithms that are utilized in the generator 102 and/or match network 104.

By way of further example, it should also be recognized that the components of the match network 104 are depicted as logical components and that the depicted components may be realized by common constructs (e.g., a common central processing unit and non-volatile memory) that are closely integrated, or the depicted components may be further distributed. For example, the functionality of the measurement section 124 may be distributed between the input sensor 116 and the output sensor 118 so that signals output from the input sensor 116 and/or output sensor 118 are digital signals that have been processed and digitalized in close connection with the sensors 116, 118, which enables the element controller 122 to directly receive processed signals from the sensors 116, 118.

The specific examples of the distribution of the depicted functions are not intended to be limiting because it is certainly contemplated that various alternatives may be utilized depending upon the type of hardware that is selected and the extent to which software (e.g., embedded software) is utilized.

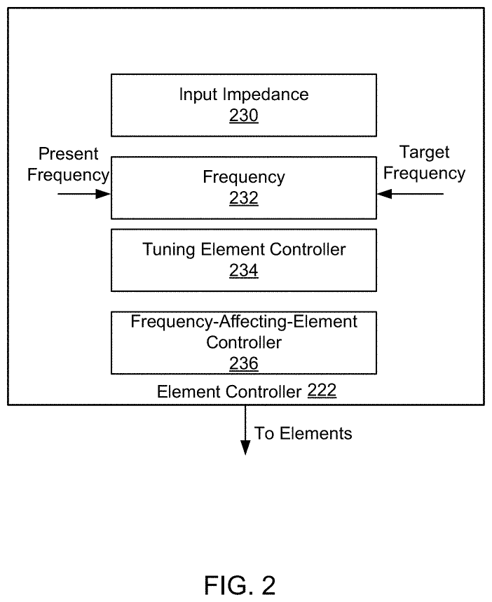

Referring next to FIG. 2, shown is a block diagram depicting exemplary components of an element controller 222 that may be utilized to implement the element controller 122 depicted in FIG. 1. As shown, the element controller 222 includes an input impedance module 230, a frequency module 232, a tuning element controller 234, and a frequency-affecting-element controller 236. The depiction of the components of the element controller 222 of FIG. 2 is a logical depiction to depict functional components of the element controller 222. When implemented, the components of the element controller 222 may be realized for common constructs and/or separate constructs. For example, the components of the element controller 222 may be implemented by software in connection with a common processor that executes the software from memory (e.g., random access memory). As another example, some of the components of the element controller 222 may be implemented by hardware components such as one or more of an applications specific integrated circuit, field programmable gate array, or programmable logic unit.

In general, the input impedance module 230 operates to obtain an input impedance at the input of the matching network 104. The input impedance is also referred to herein as a value of the impedance of the plasma load, Zp, presented to the generator 102. For example, the input impedance module 230 may calculate the input impedance using values of measured power-related parameters. As those of ordinary skill in the art will appreciate, the input sensor 116 may provide the necessary measurements of power-related parameters such as voltage, current, phase between the voltage and current, forward power, and reflected power, which may be used to calculate input impedance.

The frequency module 232 functions to obtain a present frequency (also referred to as a measured frequency) that is applied by the generator 102. There are a variety of techniques for obtaining the present frequency applied by the generator 102. One technique includes digitally sampling (e.g., with the measurement section 124) signals obtained from the input sensor 116 to obtain a stream of digital signals that include the information indicative of electrical characteristics at, at least, frequencies of a voltage output by the generator 102. The process may also include successively performing, for each of the frequencies, a single-frequency transform on the information indicative of electrical characteristics, from a time domain into a frequency domain so as to obtain an indication of a voltage level at different frequencies (e.g., to determine a predominant frequency of the voltage that is output by the generator 102). Alternatively, the generator 102 may simply communicate a value of the present frequency to the frequency module 232 of the match network 104.

In addition, the frequency module 232 may also obtain a target frequency for the generator 102. The target frequency may be selected by an operator of the plasma processing system 100, and the target frequency may be provided to the frequency module 232 via user input, which may be received via a user interface of the match controller 104 or via a network connection (e.g., from the external controller 107). For example, the target frequency may be a nominal frequency of the generator 102 (e.g., 300 kHz, 3 MHz, 13.56 MHz, or 60 MHz), or may be a frequency that is desired for a particular process. The frequency module 232 may also provide a signal that is indicative of a difference between the target frequency and the present frequency. As described further herein, the difference may be utilized by the element controller 122 to control the frequency-affecting element 115.

The tuning element controller 234 controls the tuning element 113 to change an impedance of the match network 104 to bring a value of the impedance of the plasma load, Zp, into a closer match to a desired impedance. The frequency-affecting element 115, as described further herein, operates to prompt the frequency-tuning subsystem 103 to adjust the frequency of the generator 102 to the target frequency (so the value of the impedance of the plasma load, Zp, will arrive at the desired impedance).

FIG. 3 is a block diagram depicting an exemplary variable reactance section 320 that may be used to implement the variable reactance section 120 of FIG. 1. As shown, the variable reactance section 320 includes a shunt element disposed across transmission lines of the match network 104 and a series element disposed in series along one of the transmission lines. Each of the shunt element and the series element may be coupled to the element controller 122, 222 by control lines to enable the element controller 122, 222 to adjust each of the series element and the shunt element. Each of the shunt element and the series element may be realized by one or more reactive elements. The reactive elements, for example, may be variable capacitors, which may be realized by vacuum variable capacitors or a plurality of switched capacitors (that provide a selectable capacitance that can be varied). More specifically, each of the shunt element and the series element may include a vacuum variable capacitor and/or a plurality of switched capacitors.

One of the series element or the shut element may be selected as the tuning element 113, and the other of the series element or the shut element may be selected as the frequency-affecting element 115. For example, the shut element may be the tuning element 113, and if so, then the series element operates as the frequency-affecting element 115. Similarly, the series element may be selected as the tuning element 113, and if so, then the shunt element operates as the frequency-affecting element 115. For ease of description, an exemplary mode of operation is described herein in which the shunt element operates as the tuning element 113 and the series element operates as the frequency-affecting 115, but it should be recognized that this is only exemplary and the description that follows is generally applicable to either configuration.

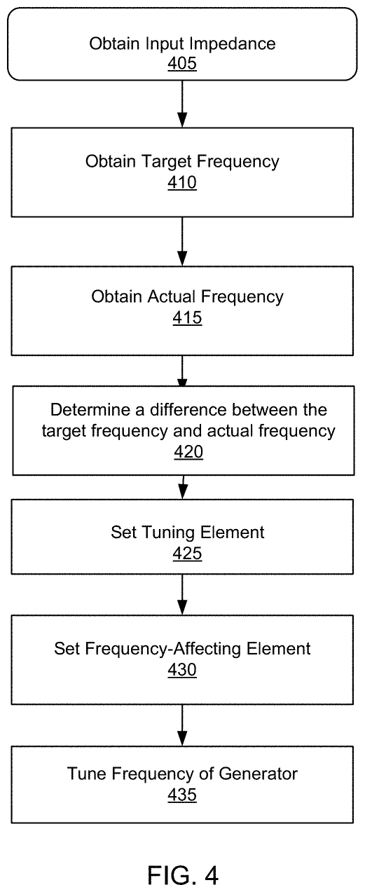

While referring to FIGS. 2 and 3, simultaneous reference is made to FIG. 4, which is a flowchart depicting a method that may be traversed in connection with embodiments herein. Although FIGS. 1-3 are referenced in connection with FIG. 4, it should be recognized that the method depicted in FIG. 4 is not limited to the depicted implementations of FIGS. 1-3.

As shown in FIG. 4, an input impedance to the match network 104 is obtained (e.g., by the input impedance module 230)(Block 405). As discussed above, the input impedance may be calculated using a voltage, current, and a phase between the voltage and current, or the impedance may be calculated using forward and reflected power. In addition, a target frequency and an actual frequency for the generator 102 are obtained (e.g., at the frequency module 232), and a difference between the target frequency and the actual frequency is determined (Blocks 410, 415, and 420). As shown in FIG. 4, both the tuning element 113 and the frequency-affecting element 115 are set (Blocks 425 and 430), and the frequency of the generator 102 is tuned (Block 435).

As a specific example, to add context to the activities carried out by the match network 104 in connection with Blocks 410-420, assume that the frequency-affecting element 115 is implemented as the series element and the series element is realized by a series capacitor. Further assume that the tuning element 113 is implemented as the shunt element and the shunt element is realized as a shunt capacitor. At any given time, the tuning element controller 234 and the frequency-affecting-element controller 236 have an awareness of the settings of the series capacitor and the shunt capacitor; thus, present values of the capacitance of the series capacitor and the shunt capacitor are known. And as discussed above, input impedance and frequency may be obtained. With these parameter values (for input impedance, frequency, and capacitance), a desired shunt capacitance may be calculated just as prior art match networks calculate a shunt capacitance setting. But in contrast to prior approaches to setting a series capacitance, the series capacitance of the present embodiment is set based upon a difference between the actual frequency and the target frequency.

Continuing with this example, the shunt capacitance, Cshunt, may be calculated as a function of the measured frequency (obtained at Block 415) and the input impedance (obtained at Block 405) so that Cshunt=f(freq_meas, Zin)(Equation 1) where freq_meas is the measured frequency (obtained at Block 415) and Zin is the input impedance (obtained at Block 405). This approach to calculating a value for Cshunt may be the same as approaches used in the prior art.

But in contrast to prior art approaches, the value, Cseries_new, for the series capacitance, Cseries, is calculated as a function of a current value of the series capacitance, Cseries_current, the actual (current) frequency (obtained at Block 415), and the target frequency, freq_target: Cseries_new=Cseries_current+(frequ_meas-freq-target)+k (Equation 2) where Cseries_new corresponds to a new, target setpoint for the series capacitor and k is gain value that may be adjusted to control how fast the series capacitor is adjusted. Thus, the change in the series capacitance (that occurs consistent with the method depicted in FIG. 4) is proportional to a difference between the current, actual frequency and the target frequency.

When the series capacitance is first set (according to Equation 2), there may be an intentional mismatch between the source impedance of the generator 102 and the impedance presented to the generator 102 by the plasma load Zp. This mismatch results in the frequency-tuning subsystem 103 of the generator 102 tuning the frequency of the generator 102 to arrive at a matched condition (Block 435). And when the matched condition is achieved, the frequency of the generator 102 will be the target frequency. Thus, the method depicted in FIG. 4 enables impedance matching to be achieved between the generator 102 and the plasma load Zp at the target frequency. As a consequence, consistency (in terms of a consistent target frequency) may be maintained during various stages of processing a workpiece within the plasma chamber 105.

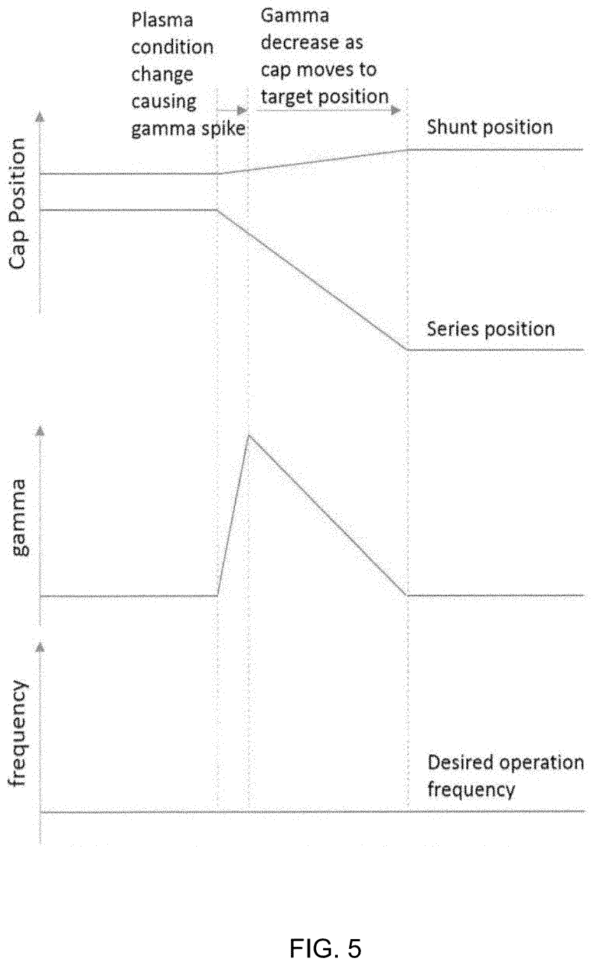

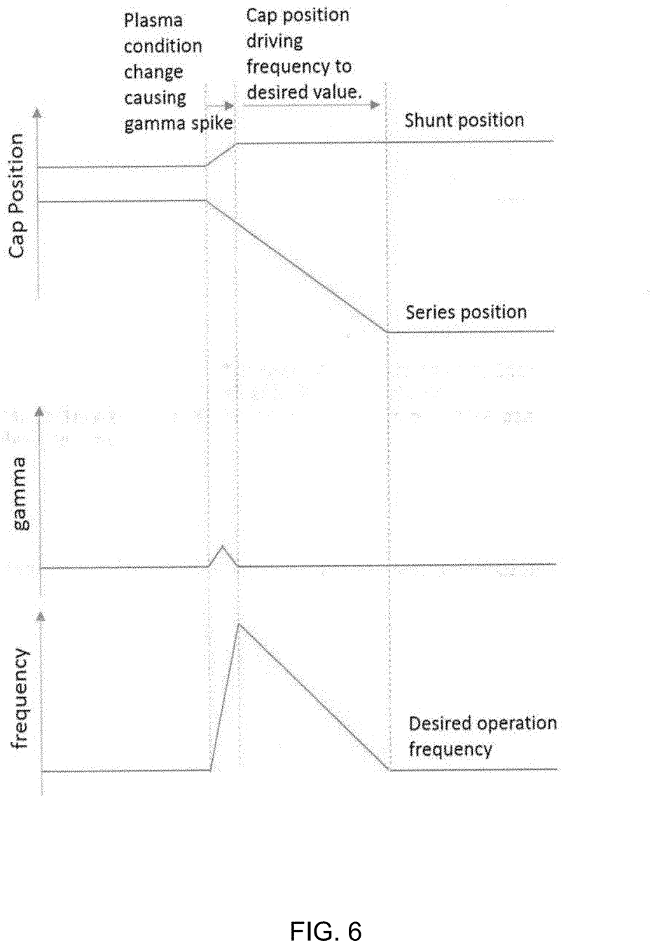

Referring to FIG. 5, shown are graphs of frequency, reflection coefficient (gamma), and capacitor position according to a prior art mode of operation with a generator that operates at a fixed frequency. FIG. 6 includes graphs of frequency, reflection coefficient (gamma), and capacitor position according to a matching approach that is consistent with the method depicted in FIG. 4 (where a frequency-affecting element, such as a series capacitor) drives the frequency of the generator 102 to a desired value. In contrast to FIG. 5 (where a tuning time, s, relatively long and there is a large spike in reflection coefficient), the control method depicted in FIG. 6 shortens a period in which reflected power is large, and a majority of the process is run at the desired, target frequency.

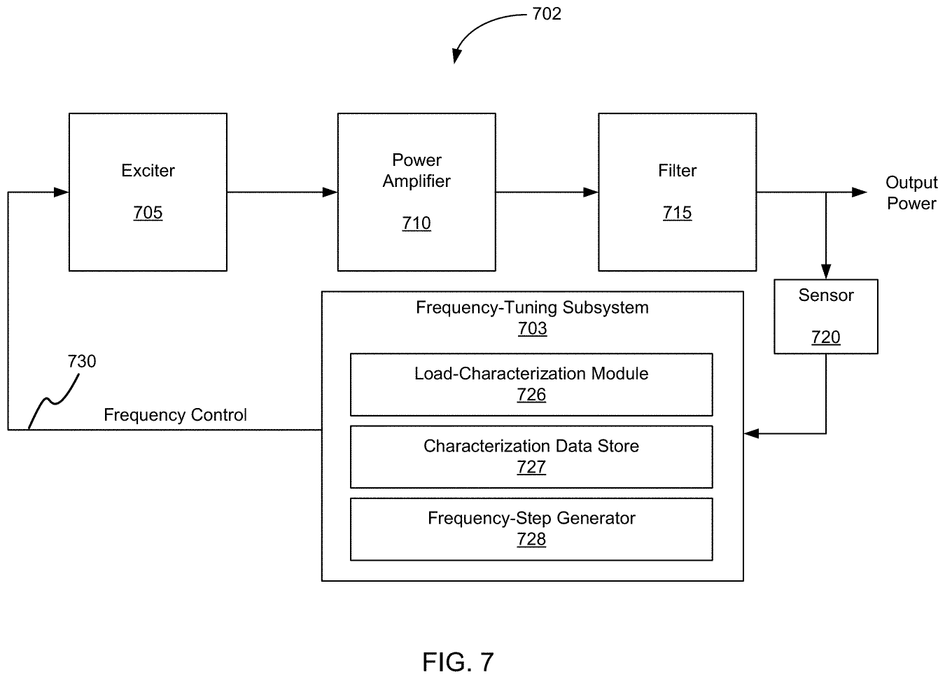

The frequency-tuning subsystem 103 of the generator 102 may implement any of a variety of frequency tuning algorithms to tune the frequency of the generator 102. Described below with reference to FIGS. 7-9 is an exemplary approach to implementing the frequency-tuning subsystem 103 in which the impedance of the plasma load is characterized as a function of generator frequency beforehand. Such characterization can be accomplished through analysis of circuit models, through preliminary testing (measurements), or a combination of these techniques. For example, the impedance of the plasma load can be measured at each of a number of different frequencies over a particular range (e.g., 13 MHz to 14 MHz). Such preliminary characterization can produce an “impedance trajectory” for the load as a function of generator frequency. This impedance trajectory can be expressed in terms of complex reflection coefficient Γ, as discussed further below. Once this impedance trajectory is known, it is possible to compute the correct frequency-step direction (positive or negative) and appropriate frequency-step size at each frequency-adjustment iteration, as explained further below

FIG. 7 is a block diagram of a generator 702 in accordance with an embodiment of this disclosure. The generator 702 includes exciter 705, power amplifier 710, filter 715, sensor 720, and frequency-tuning subsystem 703. Exciter 705 generates an oscillating signal (e.g., at RF frequencies), typically in the form of a square wave. Power amplifier 710 amplifies the signal produced by exciter 705 to produce an amplified oscillating signal. For example, in one embodiment power amplifier 710 amplifies an exciter output signal of 1 mW to 3 kW. Filter 215 filters the amplified oscillating signal to produce a signal composed of a single RF frequency (a sinusoid).

Sensor 720 measures one or more properties of the plasma load. In one embodiment, sensor 720 measures the impedance Zp of the plasma load. Depending on the particular embodiment, sensor 720 can be, for example and without limitation, a VI sensor or a directional coupler. Such impedance can alternatively be expressed as a complex reflection coefficient, which is often denoted as “F” (gamma) by those skilled in the art. Frequency-tuning subsystem 703 receives measurements from sensor 720 and processes those measurements to produce frequency adjustments that are fed to exciter 705 via frequency control line 730 to adjust the frequency generated by exciter 705. Illustrative frequency-tuning algorithms that are performed by frequency-tuning subsystem 703 are discussed in more detail below.

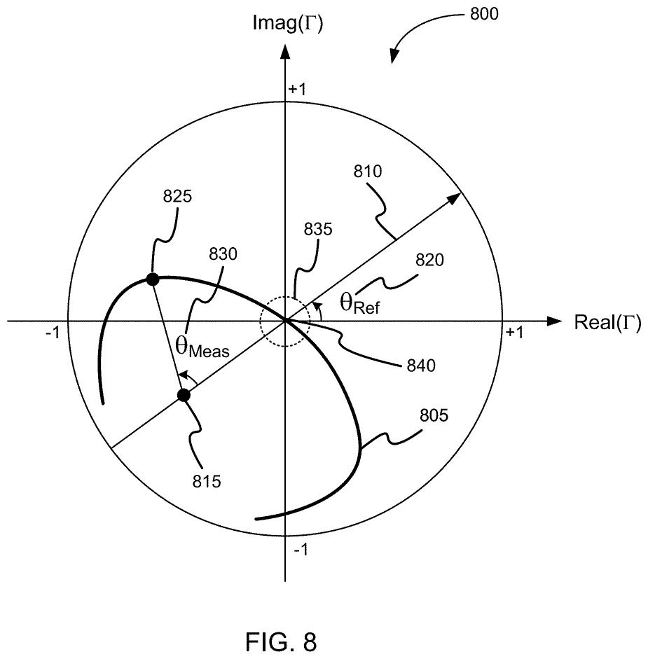

In the embodiment shown in FIG. 7, the frequency-tuning subsystem 703 includes load-characterization module 726, characterization data store 727, and frequency-step generator 728. The load-characterization module 726 receives or assists in acquiring preliminary load-impedance characterization data associated with a particular plasma load to produce an impedance trajectory (see Element 805 in FIG. 8). The data obtained during load characterization can be stored in characterization data store 727. Frequency-step generator 728 performs the computations to generate frequency adjustments (frequency steps) that are fed to exciter 705 via frequency control line 730.

As discussed further below, in some embodiments, the objective is to adjust the frequency of exciter 705, thereby changing the impedance of the plasma load, in a manner that minimizes Γ (i.e., that achieves a Γ as close to zero as possible). As mentioned above, the match network 104 may operate so that the frequency that achieves this minimum Γ may be a predetermined target frequency (e.g., 13.56 MHz). As those skilled in the art understand, an ideal complex reflection coefficient of zero corresponds to a matched condition in which the source impedance of the generator 102 and plasma-load impedances are perfectly matched. In other embodiments, the objective is not minimum Γ. Instead, frequency-tuning subsystem 703 intentionally tunes exciter 705 to generate a frequency other than the one that produces minimum Γ. Such an embodiment may be termed a “detuned” implementation.

FIG. 8 is an illustration of a complex-reflection-coefficient (Γ) plane 800 in accordance with an embodiment of this disclosure. FIG. 8 illustrates concepts relating to the algorithms carried out by frequency-tuning subsystem 725. In FIG. 8, complex reflection coefficients Γ are plotted within a unit circle. As those skilled in the art will recognize, Γ can also be plotted on a standard Smith Chart. In FIG. 8, the horizontal axis corresponds to the real part of Γ, and the vertical axis corresponds to the imaginary part of Γ. FIG. 8 shows a pre-characterized impedance trajectory 805 of the plasma load expressed in terms of Γ. As discussed above, impedance trajectory 805 can be determined in advance through analysis, testing performed with the aid of load-characterization module 726 via an appropriate user interface, or a combination thereof. Those skilled in the art will recognize that impedance trajectory 805 will not always intersect origin 840, as shown in FIG. 8. In some embodiments, impedance trajectory is shifted such that it does not pass through origin 840, in which case the minimum achievable Γ is greater than zero.

Frequency-step generator 728 of frequency-tuning subsystem 725 also receives, via a suitable user interface, a reference point 815 in Γ plane 800. In some embodiments, reference point 815 is specified in terms of a reference angle 820 and a magnitude (distance of the reference point from origin 840). As those skilled in the art will recognize, origin 840 corresponds to the point with coordinates (0, 0) at the center of the unit circle in Γ plane 800. Those skilled in the art also understand that it is straightforward to compute Cartesian coordinates for reference point 815, given reference angle 820 and a magnitude M. Specifically, the coordinates can be computed as Real(Γ)=Mcos(θ_{Ref}+π) and Imag(Γ)=Msin(θ_{Ref}+π), where the reference angle θ_{Ref} (820) is expressed in radians and M is a positive real number less than or equal to unity. In other embodiments, reference point 815 is received in terms of Cartesian coordinates (real part and imaginary part).

Once the reference point has been received, frequency-step generator 728 of frequency-tuning subsystem 725 can determine a reference vector 810. Reference vector 810 is a line that passes through reference point 815 and origin 840 of Γ plane 800, as indicated in FIG. 8. One important function of reference vector 810 is to divide Γ plane 800 into two regions, one in which the frequency associated with a measurement point 825 is higher than the optimum frequency (the region in FIG. 8 to the right of reference vector 810) and one in which the frequency associated with a measurement point 825 is lower than the optimum frequency (the region in FIG. 8 to the left of reference vector 810). By determining in which of the two regions a measurement point 825 lies, a frequency adjustment in the correct direction (positive or negative) can be made at each and every frequency-adjustment iteration.

Those skilled in the art will recognize that reference vector 810 need not be an axis of symmetry with respect to impedance trajectory 805, as expressed in terms of Γ. The choice of where to place reference point 815, which in turn determines reference vector 810, is somewhat arbitrary, though a choice should be made that makes possible the calculation of useful measurement angles 830 that support effective frequency tuning. That means choosing a reference point 815 such that the measurement angle 830 decreases as the exciter 705 frequency approaches the target frequency, a measurement angle 830 of zero corresponding to the target frequency.

Sensor 720 provides frequency-tuning subsystem 725 with frequent measurements of the impedance of the plasma load. Measurement point 825 in FIG. 8 represents one illustrative impedance measurement on impedance trajectory 805, as expressed in terms of Γ (complex reflection coefficient) in Γ plane 800. Frequency-step generator 728 of frequency-tuning subsystem 703 determines, for measurement point 825, a measurement angle 830 with respect to reference vector 810. This measurement angle 830 is scaled by a predetermined constant of proportionality K (the loop gain) to produce a frequency step (i.e., an amount by which the frequency generated by exciter 705 is to be adjusted). K is selected based on the frequency resolution of the frequency-tuning algorithm (e.g., 1 kHz vs. 1 Hz), the resolution of the measurement-angle calculations, and the particular impedance characteristics of the plasma load. The loop gain K can be different from recipe to recipe, and it can change within a given recipe in accordance with changes in the load impedance, in which case the multiple values of K employed in the recipe can be stored in a lookup table. The calculated frequency step is added to the initial or current exciter frequency to produce an adjusted frequency that is closer to the desired or target frequency corresponding to the desired plasma-load impedance. Frequency-tuning subsystem 703 then causes exciter 705, via frequency control line 730, to generate a signal at the adjusted frequency.

Also shown in FIG. 8 is a Γ threshold 835. Although not used in some implementations, the Γ threshold 335 (a value between 0 and 1) for terminating frequency adjustment, once the frequency generated by exciter 705 has reached a value that produces a plasma-load impedance that is deemed sufficiently close to the desired value.

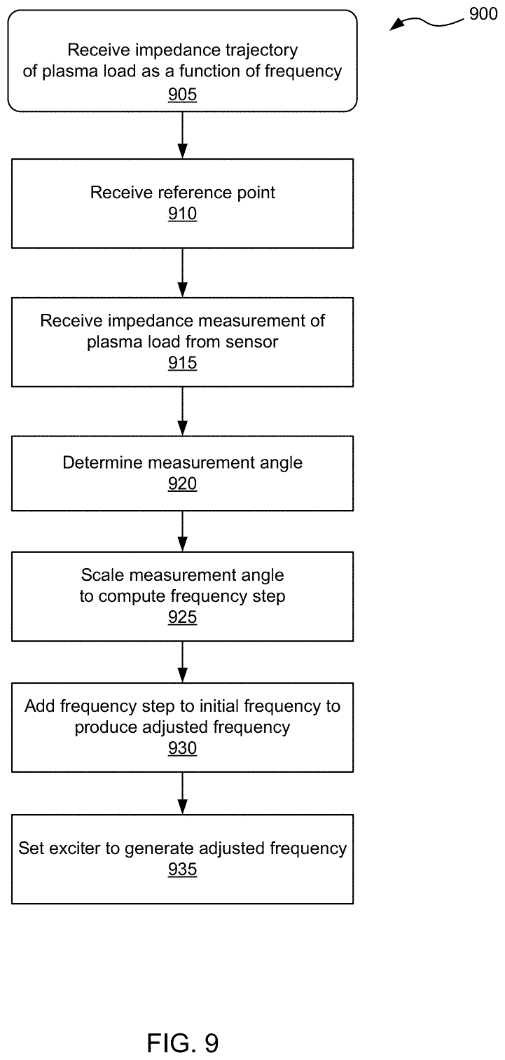

FIG. 9 is a flowchart of a method 900 for tuning the frequency of the generator 102 in accordance with an embodiment of this disclosure. The method shown in FIG. 9 may be performed by the frequency-tuning subsystem 703. At Block 905, frequency-tuning subsystem 703 receives, via load-characterization module 726, an impedance trajectory 805 for the plasma load. As explained above, impedance trajectory 805 can be expressed in terms of complex reflection coefficient (F), as shown in FIG. 8. At Block 410, frequency-step generator 728 of frequency-tuning subsystem 703 receives a reference point 815. At Block 915, frequency-step generator 728 receives an impedance measurement for the plasma load from sensor 720. At Block 920, frequency-step generator 728 determines a measurement angle 830 for the measurement point 825 corresponding to the received impedance measurement. At Block 925, frequency-step generator 728 then scales measurement angle 830 by a predetermined constant K to compute a frequency step. Note that, as method 900 commences, exciter 705 generates an oscillating signal at an initial frequency. At Block 930, frequency-step generator 728 adds the frequency step to the initial frequency generated by exciter 705 to produce an adjusted frequency. At Block 935, frequency-tuning subsystem 725, via frequency control line 730, signals exciter 705 to generate an oscillating signal at the adjusted frequency, which causes the impedance of the plasma load to change to a value closer to the desired load impedance.

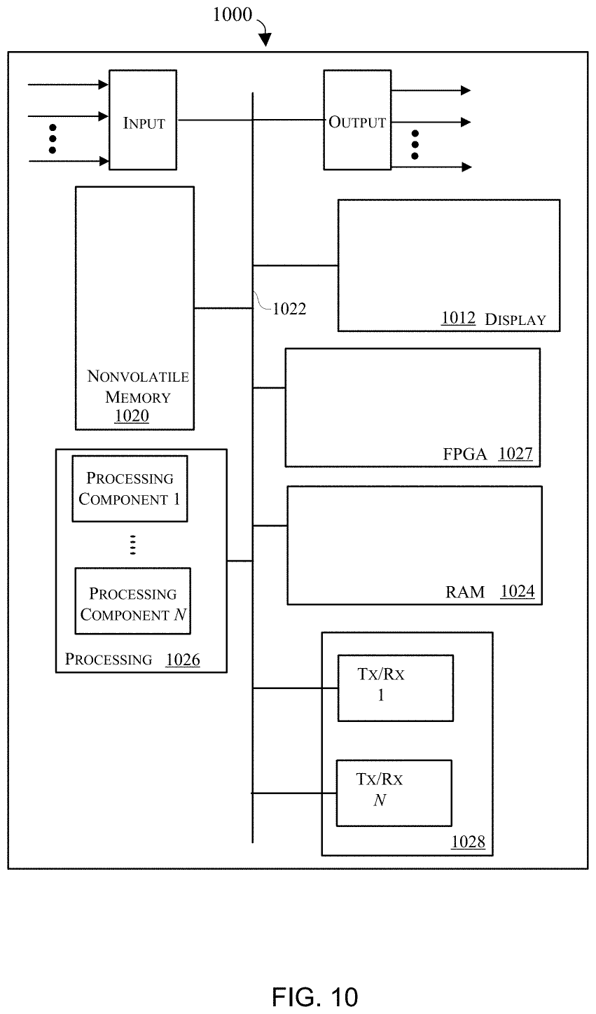

The methods described in connection with the embodiments disclosed herein may be embodied directly in hardware, in processor executable instructions encoded in non-transitory machine readable medium, or as a combination of the two. Referring to FIG. 10 for example, shown is a block diagram depicting physical components that may be utilized to realize a frequency-tuning subsystem 103, 703 the element controller 122, 222 and the component modules thereof according to an illustrative embodiment of this disclosure. As shown, in this embodiment a display portion 1012 and nonvolatile memory 1020 are coupled to a bus 1022 that is also coupled to random access memory (“RAM”) 1024, a processing portion (which includes N processing components) 1026, a field programmable gate array (FPGA) 1027, and a transceiver component 1028 that includes N transceivers. Although the components depicted in FIG. 10 represent physical components, FIG. 10 is not intended to be a detailed hardware diagram; thus, many of the components depicted in FIG. 10 may be realized by common constructs or distributed among additional physical components. Moreover, it is contemplated that other existing and yet-to-be developed physical components and architectures may be utilized to implement the functional components described with reference to FIG. 10.

Display portion 1012 generally operates to provide a user interface for a user, and in several implementations, the display is realized by a touchscreen display. For example, display portion 1012 can be used to control and interact with load-characterization module 726 in connection with characterizing a plasma load to produce an associated impedance trajectory 805. Such a user interface may also be used to input a reference point 815. The user interface may also be used to enable an operator to select a target frequency (that is provided to the frequency module 232). In general, the nonvolatile memory 1020 is non-transitory memory that functions to store (e.g., persistently store) data and machine readable (e.g., processor executable) code (including executable code that is associated with effectuating the methods described herein). In some embodiments, for example, the nonvolatile memory 1020 includes bootloader code, operating system code, file system code, and non-transitory processor-executable code to facilitate the execution of the methods (e.g., the methods described with reference to FIGS. 4 and 9) described herein.

In many implementations, the nonvolatile memory 1020 is realized by flash memory (e.g., NAND or ONENAND memory), but it is contemplated that other memory types may be utilized as well. Although it may be possible to execute the code from the nonvolatile memory 1020, the executable code in the nonvolatile memory is typically loaded into RAM 1024 and executed by one or more of the N processing components in the processing portion 1026.

In operation, the N processing components in connection with RAM 1024 may generally operate to execute the instructions stored in nonvolatile memory 1020 to realize the functionality of frequency-tuning subsystem 103, 703 and element controller 122, 222. For example, non-transitory processor-executable instructions to effectuate the methods described herein may be persistently stored in nonvolatile memory 1020 and executed by the N processing components in connection with RAM 1024. As one of ordinary skill in the art will appreciate, the processing portion 1026 may include a video processor, digital signal processor (DSP), graphics processing unit (GPU), and other processing components.

In addition, or in the alternative, the field programmable gate array (FPGA) 1027 may be configured to effectuate one or more aspects of the methodologies described herein (e.g., the methods described with reference to FIGS. 4 and 9). For example, non-transitory FPGA-configuration-instructions may be persistently stored in nonvolatile memory 1020 and accessed by the FPGA 1027 (e.g., during boot up) to configure the FPGA 1027 to effectuate the functions of frequency-tuning subsystem 103, 703 and element controller 122, 222.

The input component may operate to receive signals (e.g., from sensors 116, 118, 720) that are indicative of one or more properties of the power that is output by the generator 102 and the plasma load. The signals received at the input component may include, for example, voltage, current, forward power, reflected power, and plasma load impedance. The output component generally operates to provide one or more analog or digital signals to effectuate an operational aspect of the match network 104 and generator 102. For example, the output portion may transmit the adjusted frequency to exciter 705 via frequency control line 730 during frequency tuning. The output may also be used to control a positions of the tuning element 113 and the frequency-affecting element 115.

The depicted transceiver component 1028 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A match network comprising:
an input configured to couple to a generator;
an output configured to couple a plasma processing chamber;
a measurement section configured to provide an output indicative of an impedance of a plasma load presented to the generator;
variable reactive elements; and
a controller configured to:
obtain a target frequency of the generator;
obtain an actual frequency applied by the generator; and
adjust the variable reactive elements based on the output indicative of the impedance of a plasma load so the generator adjusts its frequency to the target frequency.

2. The match network of claim 1, comprising a frequency sensor to detect the actual frequency applied by the generator.

3. The match network of claim 1, comprising an input to receive a signal indicative of the actual frequency applied by the generator.

4. The match network of claim 1, wherein the controller comprises an input to obtain the target frequency from an operator of the match network.

5. The match network of claim 1, wherein the controller is configured to set a target frequency based upon one or more power parameter values.

6. The match network of claim 5, wherein the controller is configured to set the target frequency based upon reflected power.

7. The match of claim 1, wherein the controller comprises an input to obtain the target frequency from at least one of an operator of the match network or the generator.

8. The match network of claim 1, wherein the controller is configured to adjust one or more reactive elements that primarily affect an imaginary part of the impedance presented to the generator so the generator adjusts its frequency to the target frequency.

9. The match network of claim 8, wherein setting a position of the series element comprises setting the position as a function of a difference between the actual frequency and the target frequency.

10. A power system for a plasma processing system comprising:
a generator with a frequency-tuning subsystem;
a match network; and
means for adjusting an impedance of the match network so the frequency-tuning subsystem adjusts a frequency of power applied by the generator to a target frequency while the match network presents a desired impedance to the generator in response to variations in an impedance of a plasma load.

11. The power system of claim 10, wherein the frequency-tuning subsystem is configured to remain engaged to maintain the target frequency.

12. The power system of claim 10 wherein the match network comprises:
a series element and a shunt element; and
an element controller configured to:
obtain a value of the impedance presented to the generator;
obtain the target frequency of the generator;
obtain an actual frequency of the power applied by the generator;
set a position of the shunt element of the match network as a function of a difference between the actual frequency and the target frequency, wherein the shunt element is an adjustable reactive element of the match network; and
set a position of the series element of the match network so the generator adjusts its frequency to the target frequency.

13. A method for impedance matching, the method comprising:
applying power with a generator to a plasma load that comprises a match network;
obtaining one or more parameter values indicative of an impedance of the plasma load presented to the generator;
obtaining a target frequency of the generator;
obtaining an actual frequency of the power applied by the generator;
creating, based upon a difference between the target frequency and the actual frequency, a mismatch between a source impedance of the generator and the plasma load by adjusting a variable reactance section of a match network; and
adjusting a frequency of the generator to remove the mismatch between the source impedance of the generator and the plasma load, wherein the frequency of the generator is the target frequency when the mismatch is removed.

14. The method of claim 13, including:
setting a position of a tuning element of the match network based upon an impedance mismatch that exists, at the actual frequency, between the source impedance of the generator and the plasma load; and
setting a position of a frequency-affecting element of the match network as a function of the difference between the actual frequency and the target frequency, the position of the frequency-affecting element creates the mismatch between a source impedance of the generator and the plasma load.

15. The method of claim 14, wherein setting the position of the frequency-affecting element creates a mismatch between reactance portions of the plasma load and the source impedance of the generator when there is a difference between the target frequency and the actual frequency.

16. The method of claim 15, wherein setting a position of the tuning element of the match network comprises setting a position of a shunt element arranged in parallel with a plasma chamber, and setting a position of the frequency-affecting element comprises adjusting a position of a series element arranged in series with the plasma chamber.

17. The method of claim 13, wherein creating the mismatch between a source impedance of the generator and the plasma load comprises adjusting a series capacitor of the match network, and the method comprises:
simultaneously adjusting the frequency of the generator while adjusting a shunt capacitor of the match network.

18. A non-transitory computer-readable medium comprising instructions for operating a match network, for execution by a processor or for configuring a field programmable gate array, the instructions comprising instructions to:
obtain one or more parameter values indicative of an impedance of a plasma load;
obtain a target frequency of the generator;
obtain an actual frequency of the power applied by the generator; and
create, based upon a difference between the target frequency and the actual frequency, a mismatch between a source impedance of the generator and the plasma load by adjusting a variable reactance section of a match network.

19. The non-transitory computer-readable medium of claim 18 comprising instructions to obtain the target frequency from an operator of the match network.

20. The non-transitory computer-readable medium of claim 18 comprising instructions to set a target frequency based upon one or more power parameter values.
